(19) United States
(12) Patent Application Publication
(10) Pub. No.: US 2007/0236893 A1
(43) Pub. Date: Oct. 11, 2007

(54) EXTERNAL HARD DISK DRIVE RACK

(75) Inventor: ZHENG-HENG SUN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,640

(22) Filed: Sep. 1, 2006

(30) Foreign Application Priority Data
Apr. 7, 2006 (CN) 200610060229.X

(51) Int. Cl. H05K 5/00

(52) U.S. Cl. 361/724

(57) ABSTRACT

An external hard disk drive (ext.HDD) rack includes an enclosure. The enclosure defines at least one receiving space for receiving an ext.HDD, at least one latching element movably installed in the enclosure, and at least one resilient element installed in the enclosure at a rear end of the receiving space for pushing the ext.HDD out of the at least one receiving space. The latching element includes a main body of which at least one portion extends into the at least one receiving space for holding the ext.HDD in the receiving space.

### FIELD OF THE INVENTION

The present invention relates to an external hard disk drive (ext.HDD) rack.

### 2. DESCRIPTION OF RELATED ART

Generally speaking, an external hard disk drive (ext.HDD) is a hard disk drive which is placed outside of a computer and connected to the computer to exchange data therebetween when in need. This provides an easily removable form of mass storage. However, when using an ext.HDD it is generally placed somewhere near the computer occupying precious desktop space and may be at risk of damage since it is not fixed in position.

What is desired, therefore, is to provide ext.HDD rack which can receive an ext.HDD therein thereby saving space and providing protection.

### SUMMARY OF THE INVENTION

An exemplary external hard disk drive (ext.HDD) rack includes an enclosure. The enclosure defines at least one receiving space for receiving an ext.HDD, at least one latching element movably installed in the enclosure, and at least one resilient element installed in the enclosure at a rear end of the receiving space for pushing the ext.HDD out of the at least one receiving space. The latching element includes a main body of which at least one portion extends into the at least one receiving space for holding the ext.HDD in the receiving space.

Other advantages and novel features will become more apparent from the following detailed description when taken in conjunction with the accompanying drawings, in which:

### BRIEF DESCRIPTION OF THE DRAWINGS

FIG. 1 is an isometric view of an external hard disk drive (ext.HDD) rack in accordance with a preferred embodiment of the present invention;

FIG. 2 is a cross-sectional view taken along line II-II of FIG. 1;

FIG. 3 is an enlarged view of part III of FIG. 2; and

FIG. 4 an isometric view of a computer case which encloses an ext.HDD rack of FIG. 1.

### DETAILED DESCRIPTION OF THE INVENTION

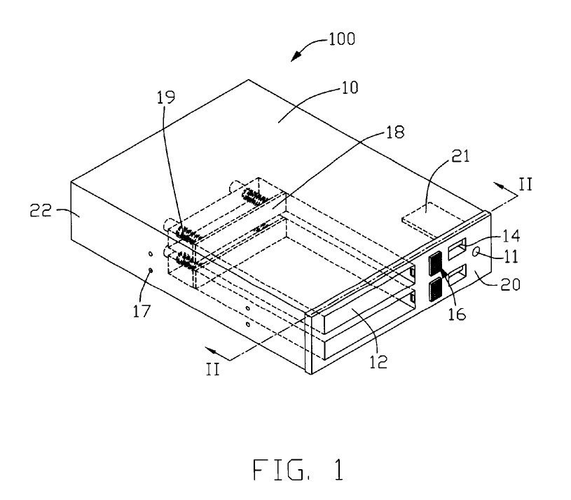

Referring to FIG. 1, an external hard disk drive (ext.HDD) rack 100 in accordance with a preferred embodiment of the present invention is shown. The ext.HDD rack 100 includes a generally quadrate enclosure 10. The enclosure 10 defines two receiving spaces 12 for accommodating ext.HDDs, the receiving spaces 12 can be more than two according to need. The enclosure 10 further includes a connecting printed circuit board (PCB) 21 therein for connecting the ext.HDDs to an electronic device such as a computer via corresponding communicating interfaces such as Universal Serial Bus (USB) interfaces.

A first through hole 111 and two second through holes 14 are defined in a front panel 20 of the enclosure 10. The first through hole 11 and the second through holes 14 are used for receiving the communicating interfaces of the connecting PCB 21. Two latching elements 16 are installed on the front panel 20 corresponding to the receiving spaces 12. Two blocking boards 18 are respectively installed in the receiving spaces 12, and a plurality of resilient elements 19 such as two springs are installed between a rear end of each receiving space 12 and corresponding blocking board 18. A plurality of mounting holes 17 are defined in two side panels 22 of the enclosure 10 for fixing the enclosure 10 on a computer case.

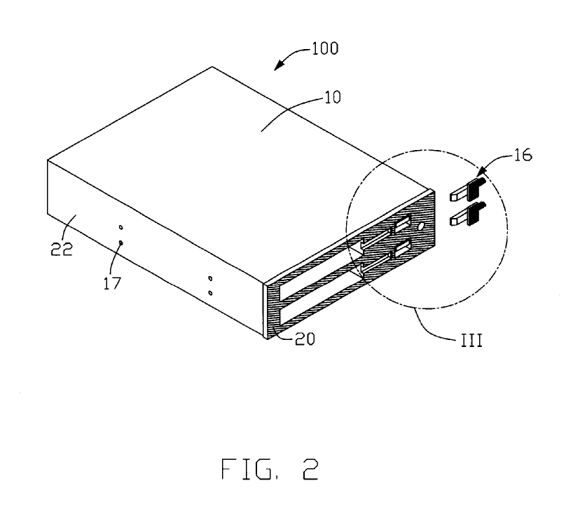

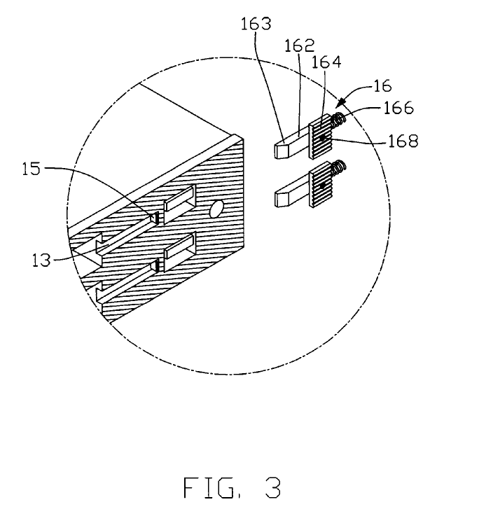

Referring also to FIGS. 2 and 3, each latching element 16 includes a main body 162, a sliding portion 164 mounted on a rear portion of the main body 162 via a fastener such as a screw 168, and a resilient member 166 such as a spring. Two longitudinal grooves 13 are defined within the front panel 20 of the enclosure 10 respectively adjoining the receiving spaces 12, and a blocking tab 15 is mounted in one end of each groove 13. The main body 162 of each latching element 16 is received in the corresponding groove 13 and can be slidably moved a certain distance by pushing the sliding portion 164. The main body 162 of each latching element 16 includes a positioning portion 163 formed at one end thereof, and the positioning portion 163 defines a slanted surface. Two ends of each resilient member 166 are respectively connected to another end of the corresponding main body 162 and the corresponding blocking tab 15.

When an ext.HDD (not shown) is inserted into one of the receiving spaces 12 of the enclosure 10 of the ext.HDD rack 100, the ext.HDD urges the slanted surface of the positioning portion 163 of the corresponding main body 162 to push the main body 162 into the groove 13, and the resilient member 166 is compressed by the main body 162. The ext.HDD is continually moved into the receiving space 12, and the blocking board 18 is pushed inwardly by the ext.HDD. The resilient elements 19 are simultaneously compressed by the blocking board 18. After a trailing edge of the ext.HDD passes beyond the groove 13 it is received completely in the receiving space 12, and the resilient member 166 is restored to push the main body 162 back, thereby the ext.HDD is blocked in the receiving space 12 by the positioning portion 163 of the main body 162. To detach the ext.HDD from the enclosure 10, the sliding portion 164 is slid away from the receiving space 12 to retract the positioning portion 163 into the groove 13 from the receiving space 12, the resilient elements 19 are restored to push the ext.HDD outward from the receiving space 12, the ext.HDD is then ready to be pulled out from the receiving space 12.

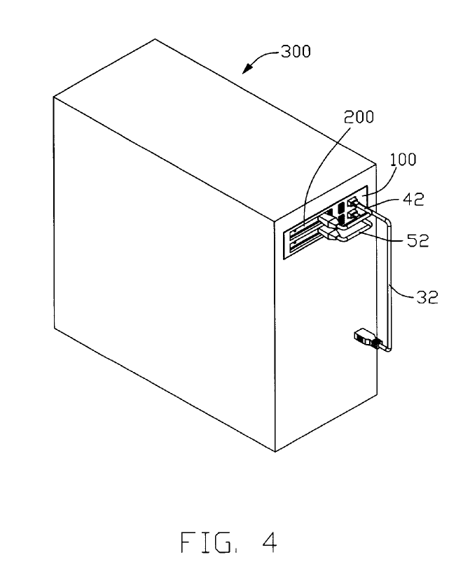

Referring also to FIG. 4, the ext.HDD rack 100 with two ext.HDDs 200 is installed in a computer case 300. The connecting PCB 21 in the enclosure 10 of the ext.HDD rack 100 is connected to the corresponding interface of the computer case 300 via a cable 32 inserted in the first through hole 11. The ext.HDDs 200 are connected to the connecting PCB 21 via two cables 42, 52, and the ext.HDDs 200 can communicate with a motherboard in the computer case 300.

With the ext.HDDs 200 installed in the ext.HDD rack 100 and the ext.HDD rack 100 then installed in the computer case 300, desktop space is saved and protection is provided to the ext.HDDs 200.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment of the invention.

What is claimed is:

1. An external hard disk drive (ext.HDD) rack comprising:
an enclosure defining at least one receiving space for receiving an ext.HDD, at least one latching element movably installed in the enclosure, and at least one resilient element installed in the enclosure at a rear end of the receiving space for pushing the ext.HDD out of the at least one receiving space, the at least one latching element comprising a main body of which at least one portion extends into the at least one receiving space for holding the ext.HDD in the receiving space.

2. The ext.HDD rack as claimed in claim 1, wherein the latching element further comprises a resilient portion, a front panel of the enclosure defines a groove communication with the at least one receiving space, the main body is received in the groove and abuts against the resilient portion.

3. The ext.HDD rack as claimed in claim 1, wherein the at least one portion is a positioning portion formed at one end of the main body of the latching element for blocking the ext.HDD.

4. The ext.HDD rack as claimed in claim 1, wherein the latching element further comprises a sliding portion mounted to the main body and exposed out of the enclosure.

5. The ext.HDD rack as claimed in claim 1, further comprising a blocking board attached to the at least one resilient element.

6. The ext.HDD rack as claimed in claim 1, wherein the enclosure further comprises a connecting printed circuit board (PCB) comprising a plurality of communicating interfaces for connecting the ext.HDD to a computer when the rack and the ext.HDD are received in the computer.

7. The ext.HDD rack as claimed in claim 7, wherein a plurality of through holes are defined in the enclosure for receiving the communicating interfaces of the connecting PCB.

8. A computer comprising:
a case;
an external hard disk drive (ext.HDD) rack installed in the case, the ext.HDD rack defining at least one receiving space for receiving an ext.HDD, at least one latching element movably installed in the ext.HDD rack for holding the ext.HDD in the receiving space, a connecting printed circuit board (PCB) installable in the ext.HDD rack; and
at least one cable provided for electrically connecting the ext.HDD to the computer allowing communicating therebetween.

9. The computer assembly as claimed in claim 8, wherein the latching element comprising a main body of which at least one portion extends in the at least one receiving space for holding the ext.HDD in the receiving space.

10. The computer assembly as claimed in claim 9, wherein the enclosure defines a groove in communication with the at least one receiving space receiving the main body of the latching element, the latching element further comprises a resilient member received in the groove and abutting against the main body of the latching element.

11. The computer as claimed in claim 9, wherein the at least one portion of the main body of the latching element is a positioning portion formed at one end of the main body for blocking the ext.HDD.

12. The computer as claimed in claim 9, wherein the latching element further comprises a sliding portion mounted on the main body and accessible from outside of the ext.HDD rack.

13. The computer as claimed in claim 8, further comprising at least one resilient element installed in the ext.HDD rack at a rear end of the at least one receiving space and compressed when the ext.HDD is held in the at least one receiving space.

14. The computer as claimed in claim 8, wherein the connecting PCB comprises a plurality of communicating interfaces, a plurality of holes is defined in the ext.HDD rack for receiving the communicating interfaces of the connecting PCB.

15. A computer comprising:
a computer case with a plurality of interfaces;
a rack detachably installed in the case, the rack defining at least one receiving space, at least one latching element movably installed in the rack, a connecting printed circuit board (PCB) installed in the rack;
at least one data storage device installed in the at least one receiving space of the rack and electrically coupling to the connecting PCB, and
a cable provided at outside of the computer case for electrically connecting the connecting PCB to one of the interfaces of the computer thereby allowing communicating therebetween, wherein
the at least one latching element is moveable between a retracted position at which the at least one data storage device is capable of moving out of the at least one receiving space and an extended position at which the at least one latching element holds the at least one data storage device in the at least one receiving space.

16. The computer as claimed in claim 15, wherein the at least one data storage device is electrically coupling to the connecting PCB via an additional cable exposed outside of the computer case.

17. The computer as claimed in claim 15, wherein the enclosure comprises a panel defining at least one groove in communication with the at least one receiving space, and the latching element comprises a main body extendable into the at least one receiving space and a resilient member received in the groove and abutting against the main body of the latching element for driving the main body from the retracted position to the extended position to hold the at least one data storage device in the at least one receiving space.

18. The computer as claimed in claim 17, wherein the at least one groove is defined within the panel, and the latching element further comprises a sliding portion secured to the main body and accessible from outside of the rack for driving the main body from the extended position to the retracted position.

19. The computer as claimed in claim 15, further comprising at least one resilient element installed in the rack at a rear end of the at least one receiving space and compressed when the at least one data storage device is held in the at least one receiving space.
